(19) United States
(12) Patent Application Publication
(10) Pub. No.: US 2026/0231506 A1
(43) Pub. Date: Aug. 6, 2026

(54) SEMICONDUCTOR STRUCTURE AND FABRICATION METHOD THEREOF

(71) Applicant: NANYA TECHNOLOGY CORPORATION, New Taipei City (TW)

(72) Inventors: Ying-Cheng Chuang, New Taipei City (TW); Chung-Lin Huang, New Taipei City (TW)

(73) Assignee: NANYA TECHNOLOGY CORPORATION, New Taipei City (TW)

(21) Appl. No.: 19/047,581

(22) Filed: Feb. 6, 2025

(51) Int. Cl. H10D 64/27; H01L 21/762; H10D 64/66

(52) U.S. Cl. CPC H10D 64/513; H10D 64/664; H10W 10/0145; H10W 10/17

(57) ABSTRACT

A semiconductor structure is provided. The semiconductor structure includes a substrate, word lines, a first barrier layer and work function control structures. The word lines are located in word line trenches of the substrate. The first barrier layer is disposed on top surfaces of the word lines. The work function control structures are disposed over the word lines. Each work function control structure includes a first doped region and a second doped region, with the first doped region positioned closer to the word lines than the second doped region. The first doped region and the second doped region are composed of a semiconductor material and contain a same dopant species, and the first doped region has a higher dopant concentration than the second doped region.

### BACKGROUND

### Technical Field

The present invention relates to a semiconductor structure and fabrication method thereof

### Description of Related Art

The buried word line (BWL) technology plays a crucial role in enhancing integration and performance in semiconductor memory, particularly in dynamic random-access memory (DRAM). By embedding the word line within the substrate, BWL not only effectively conserves surface space but also reduces capacitive coupling and interference between adjacent components, thereby improving overall signal integrity and power efficiency. However, as devices are further miniaturized, the fabrication process for BWL technology faces new challenges, one of which is the leakage issue caused by gate-induced drain leakage (GIDL).

The GIDL issue becomes more pronounced in highly integrated devices. With device miniaturization and the application of BWL technology, the GIDL phenomenon increasingly affects device stability, especially in high-density DRAM. When the gate voltage of a transistor increases, GIDL causes an increase in leakage current, which raises power consumption and undermines memory reliability. To address this problem, modern processes often use high-k dielectric materials or alternative structural designs to reduce leakage current, thereby supporting further miniaturization and performance optimization of BWL technology.

### SUMMARY

The present invention provides a semiconductor structure and a fabrication method thereof. In some embodiments of this disclosure, the work function control structure is positioned above a word line. the work function control structure comprises a first doped region and a second doped region, with the first doped region has a higher dopant concentration than the second doped region. By employing this configuration, the GIDL issue can be mitigated.

In accordance of some embodiments of the present disclosure, a semiconductor structure includes a substrate, word lines, a first barrier layer and work function control structures. The word lines are located in word line trenches of the substrate. The first barrier layer is disposed on top surfaces of the word lines. The work function control structures are disposed over the word lines. Each work function control structure includes a first doped region and a second doped region, with the first doped region positioned closer to the word lines than the second doped region. The first doped region and the second doped region are composed of a semiconductor material and contain a same dopant species, and the first doped region has a higher dopant concentration than the second doped region.

In some embodiments, the first doped region and second doped region are physically connected.

In some embodiments, a second barrier layer is disposed over the work function control structures, and a cap layer is disposed over the second barrier layer and embedded in the substrate.

In some embodiments, the first doped regions are laterally located between the second doped regions and sidewalls of the word line trenches.

In some embodiments, the semiconductor material is silicon, and the same dopant species is phosphorus or arsenic. The word lines are titanium nitride.

In some embodiments, a fabrication method of a semiconductor structure includes the following steps: forming word line trenches in a substrate; forming word lines in the word line trenches; forming a first barrier layer on top surfaces of the word lines; and forming work function control structures over the word lines. Each work function control structure includes a first doped region and a second doped region, with the first doped region positioned closer to the word lines than the second doped region. The first doped region and the second doped region are composed of a semiconductor material and contain a same dopant species, and the first doped region has a higher dopant concentration than the second doped region.

In some embodiments, a method for forming the work function control structures includes the follow steps: forming a first semiconductor material layer in the word line trenches; etching the first semiconductor material layer to release top spaces of the word line trenches and to form the first doped regions of the work function control structures; forming a second semiconductor material layer on the first doped regions in the word line trenches; and etching the second semiconductor material layer to release a portion of the top spaces of the word line trenches and to form the second doped regions of the work function control structures.

In some embodiments, a first barrier material layer is formed over top surfaces o the word lines and sidewalls of the word line trenches. The first semiconductor material layer is formed on the first barrier material layer. The first barrier material layer is etched during etching the first semiconductor material layer, and the first barrier layer is formed after etching the first barrier material layer. The first barrier layer extends beyond top surfaces of the first doped regions. The second semiconductor material layer is formed on the first doped regions. The first barrier layer is laterally located between the second semiconductor material layer and the sidewalls of the word line trenches.

In some embodiments, a mask layer is formed on the substrate. An etching process is performed on the substrate, during which the mask layer is used to define the plurality of word line trenches. The first barrier material layer is formed on the mask layer and in the word line trenches. The first semiconductor material layer is formed on the first barrier material layer and in the word line trenches. The first semiconductor material layer is separated from the mask layer by the first barrier material layer. The first barrier material layer is etched to remove a portion of the first barrier material layer on the mask layer. The second semiconductor material layer is formed on the mask layer and in the word line trenches. The second semiconductor material layer is in contact with the mask layer.

In some embodiments, a method for forming the plurality of work function control structures includes the following steps. A first barrier material layer is formed over top surfaces of the word lines and sidewalls of the word line trenches. A semiconductor material layer is formed on the first barrier material layer, wherein the semiconductor material layer includes a first region at bottom and a second region at top, with the first region in contact with the first barrier material layer, wherein the first region and the second region are composed of the semiconductor material and contain the same dopant species, and the first region has a higher dopant concentration than the second region. The semiconductor material layer is etched to form the first doped region and the second doped region. The first barrier material layer is etched during etching the semiconductor material layer, and the first barrier layer is formed after etching the first barrier material layer

### BRIEF DESCRIPTION OF THE DRAWINGS

FIGS. 1A to 1L are schematic cross-sectional views of the manufacturing method of a semiconductor structure of the embodiment of the present invention.

FIGS. 2A and 2B are perspective top views of the manufacturing method of a semiconductor structure of the embodiment of the present invention.

FIGS. 3A to 3C are schematic cross-sectional views of the manufacturing method of a semiconductor structure of the embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

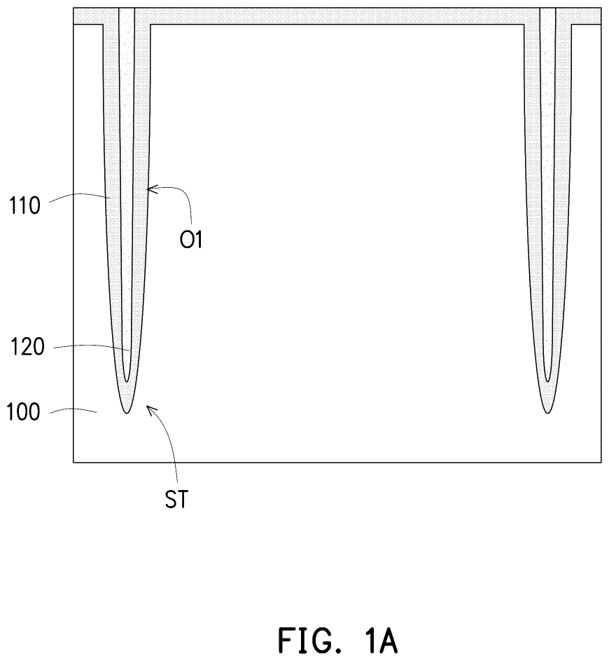

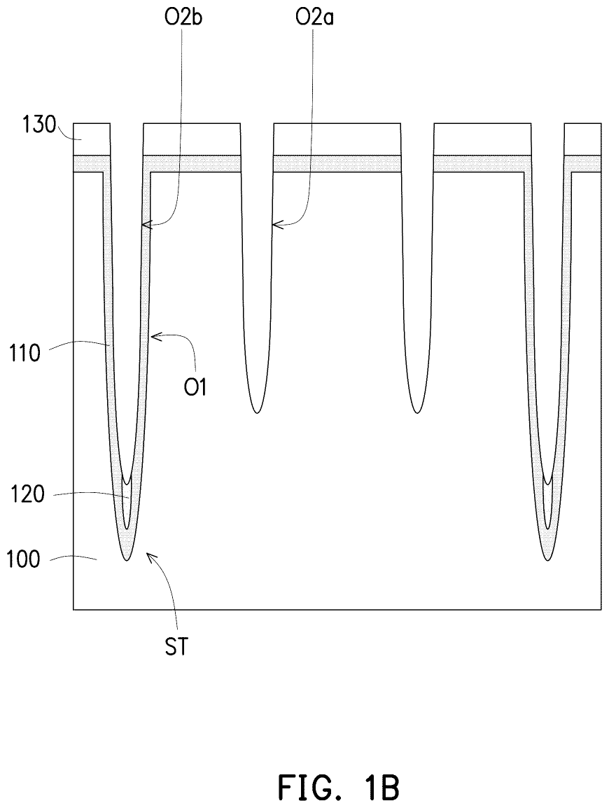

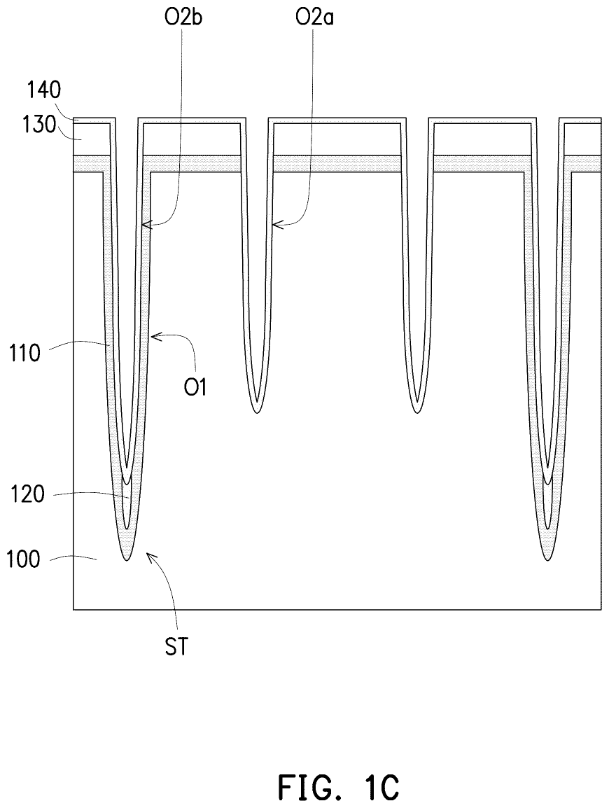

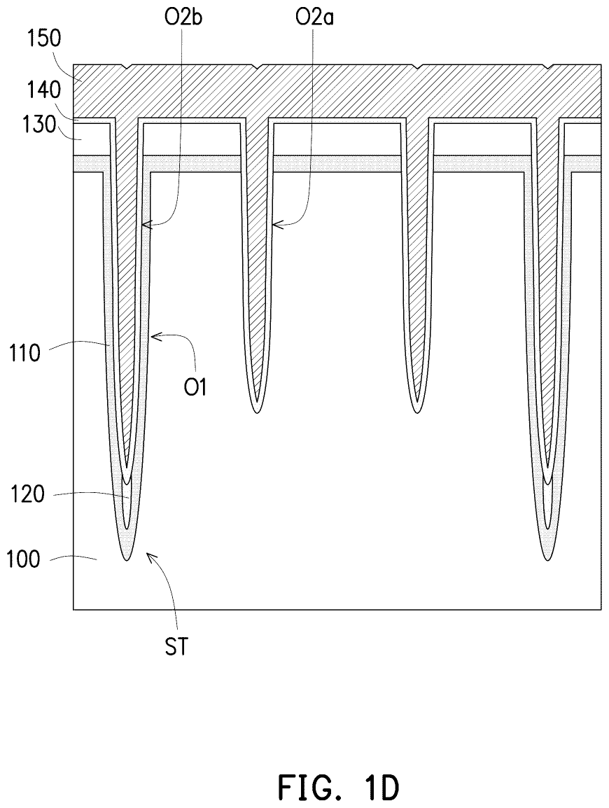

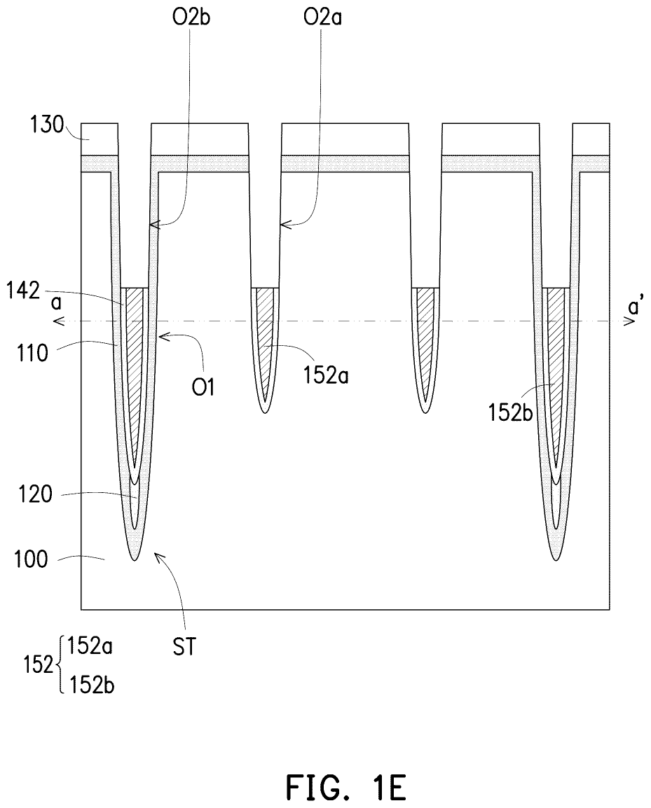

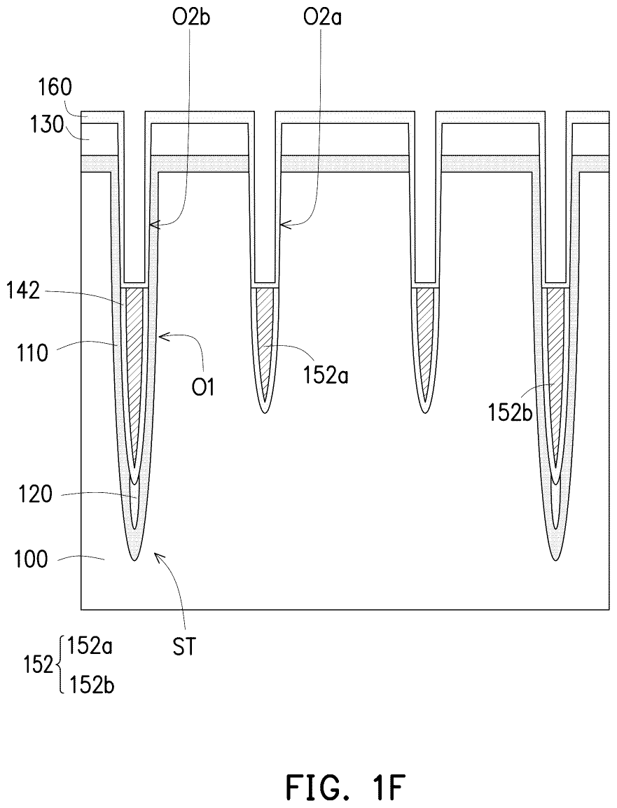

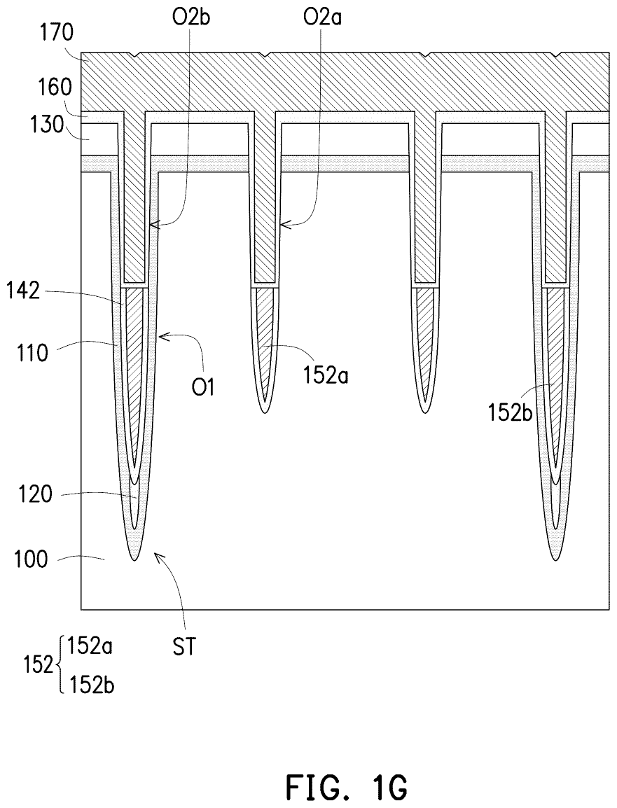

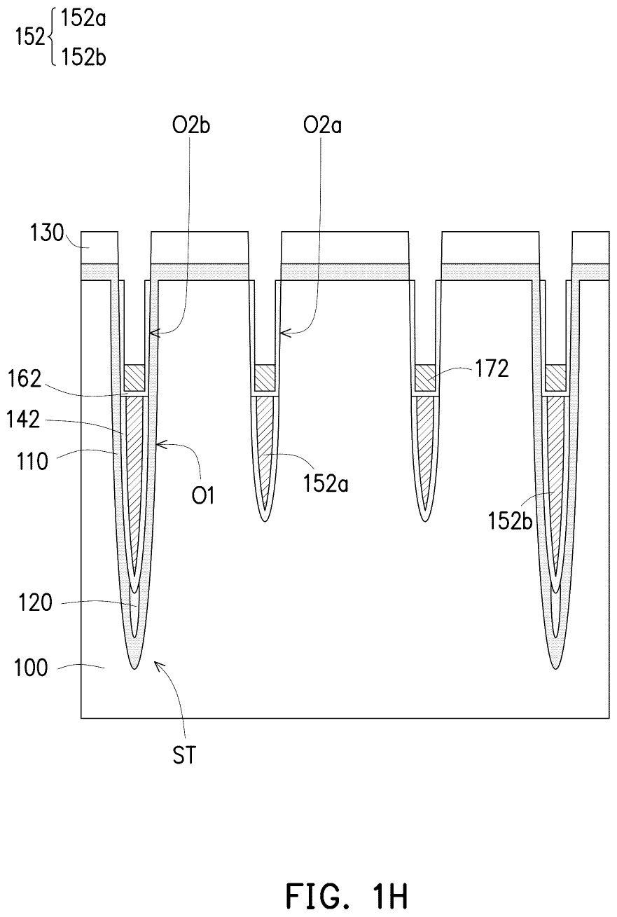

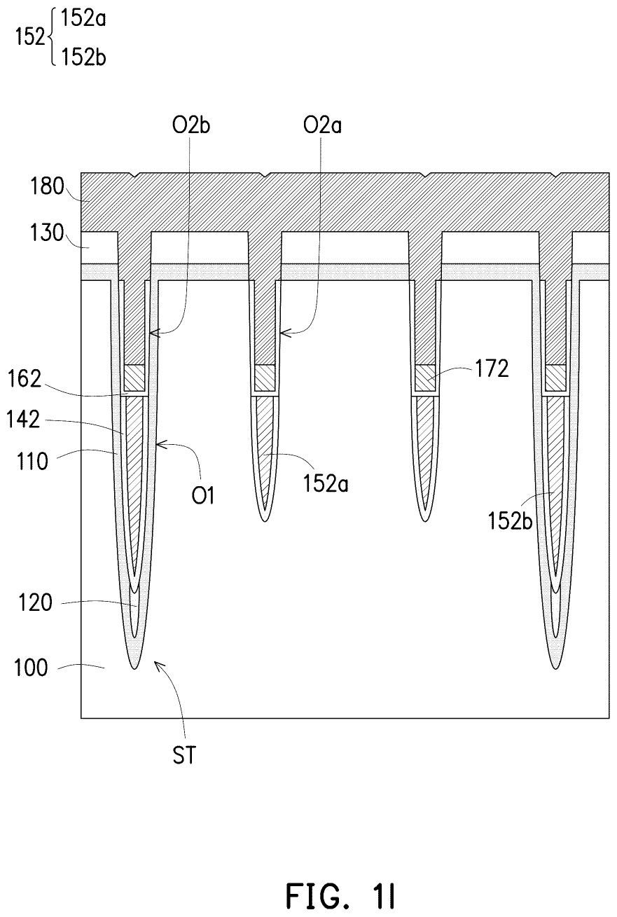

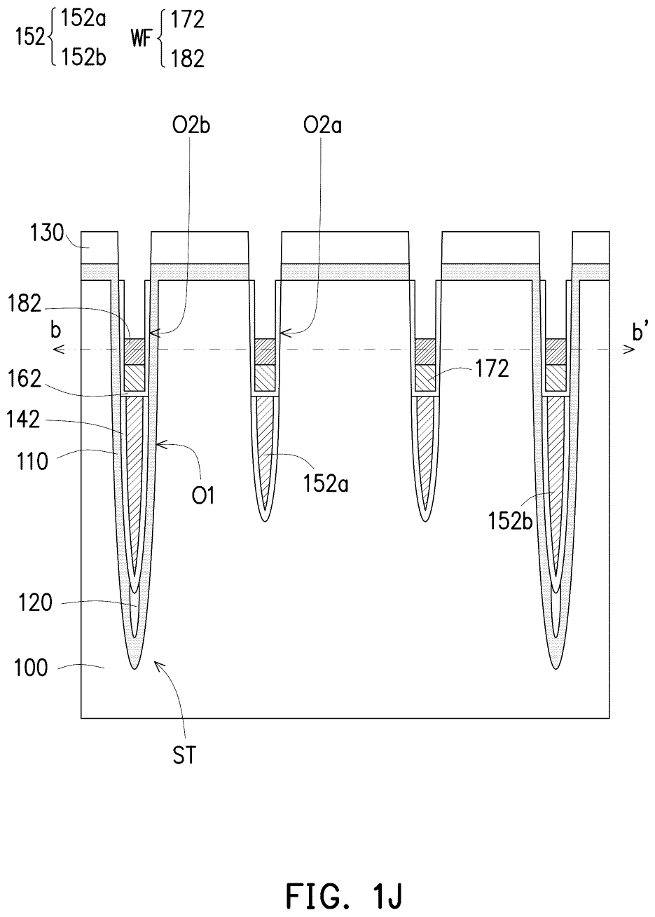

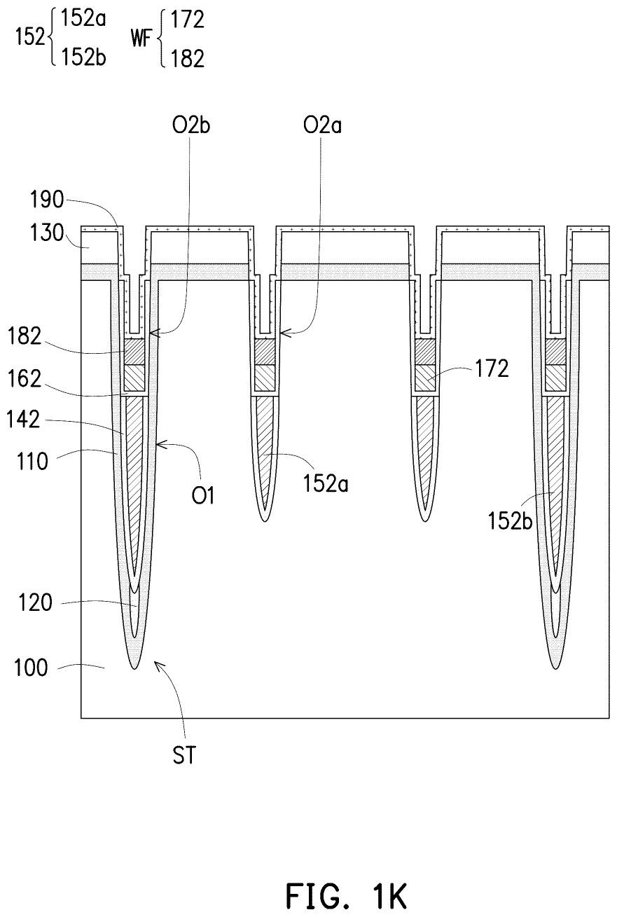

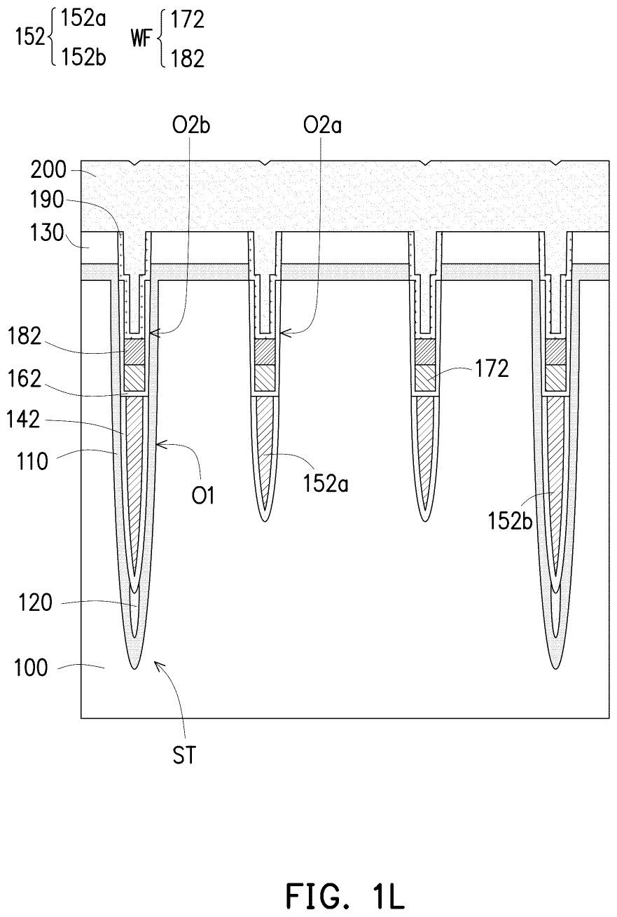

FIGS. 1A to 1L are schematic cross-sectional views of the manufacturing method of a semiconductor structure of the embodiment of the present invention. Referring to FIG. 1A, a substrate 100 is provided. The substrate 100 includes a semiconductor material, such as silicon, germanium, silicon carbide, gallium nitride, silicon-germanium, or other semiconductor materials.

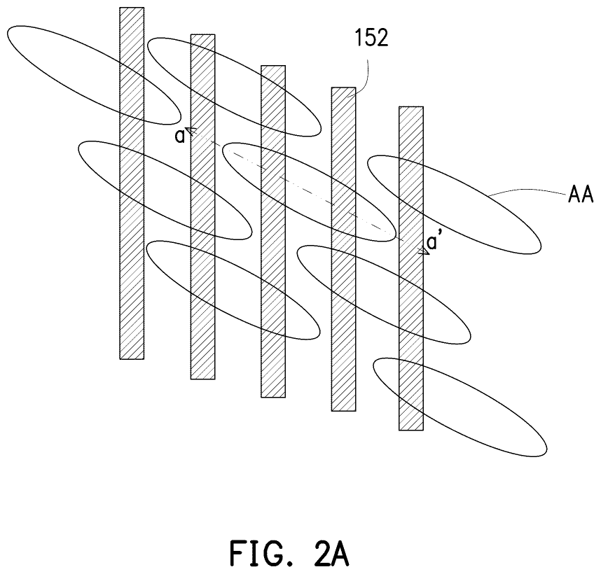

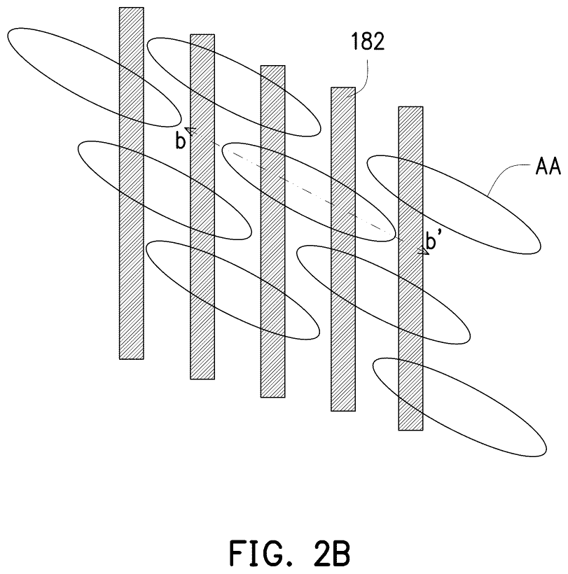

The substrate 100 includes active areas AA (not shown in FIG. 1A; refer to FIGS. 2A and 2B). The active areas AA are isolated from each other. Multiple first openings O1 are formed in the substrate 100. An isolation material 110 is filled into the first openings O1 to form shallow trench isolation (STI) structures ST embedded in the substrate 100. The STI structures ST are located between the active areas AA.

In some embodiments, when filling the first openings O1 with isolation material 110, each or part of the first openings O1 is not fully filled by the isolation material 110. In such cases, a filling layer 120 is used to occupy the remaining space in the first openings O1, and each or part of the STI structures ST includes not only isolation material 110 but also the filling layer 120. In some embodiments, the isolation material 110 includes oxide, such as silicon oxide or other insulating materials. In some embodiments, the filling layer 120 includes nitride, such as silicon nitride or other insulating materials.

In some embodiments, the isolation material 110 not only disposed within the first openings O1 but also covers the top surface of the substrate 100; however, this disclosure is not limited thereto.

Referring to FIG. 1B, a mask layer 130 is formed above the substrate 100. In some embodiments, the mask layer 130 is formed on the isolation material 110. An etching process is performed on the substrate 100, during which the mask layer 130 is used to define multiple word line trenches O2a and O2b. The word line trench O2b extends into the STI structures ST, while the word line trench O2a penetrates the isolation material 110 and extends into the substrate 100. Due to the different etching rates of the STI structures ST and the substrate 100, the depths of word line trenches O2a and O2b vary.

Referring to FIG. 1C, a gate dielectric material layer 140 is formed on the mask layer 130 and along the sidewalls of the word line trenches O2a and O2b. The gate dielectric material layer 140 may be deposited using one or more techniques, such as atomic layer deposition (ALD), in-situ steam generation (ISSG), or other suitable methods. In some embodiments, to minimize the residual stress associated with the gate dielectric material layer 140, a blanket oxide layer is first deposited using ALD, which results in lower residual stress. This oxide layer is then thickened using ISSG to achieve the desired final thickness for the gate dielectric material layer 140. In some embodiments, the gate dielectric material layer 140 includes oxide, such as silicon oxide; however, the present disclosure is not limited thereto. In other embodiments, the gate dielectric material layer 140 may include silicon nitride, silicon oxynitride, hafnium oxide, zirconium oxide, aluminum oxide, or other insulating materials with a dielectric constant higher than that of silicon oxide.

Referring to FIGS. 1D and 1E, word lines 152 are formed within the word line trenches O2a and O2b in the substrate 100. A conductive material 150 is deposited into the word line trenches O2a and O2b and on the gate dielectric layer 140, as shown in FIG. 1D. In some embodiments, the conductive material 150 includes aluminum (Al), copper (Cu), tungsten (W), titanium (Ti), tantalum (Ta), titanium-aluminum alloy (TiAl), titanium aluminum nitride (TiAlN), tantalum carbide (TaC), tantalum carbonitride (TaCN), tantalum silicon nitride (TaSiN), manganese (Mn), zirconium (Zr), titanium nitride (TiN), tungsten nitride (WN), tantalum nitride (TaN), ruthenium (Ru), titanium silicon nitride (TiSiN), other suitable materials, or combinations thereof.

FIG. 2A shows a cross-sectional schematic corresponding to the position along line a-a′ in FIG. 1E, illustrating the word lines 152 and the active areas AA of the substrate 100. Referring to FIG. 1E and FIG. 2A, the conductive material 150 is etched to remove the excess material outside of the word line trenches O2a and O2b, forming the word lines 152, with a recess formed above the word lines 152. In some embodiments, while etching the conductive material 150, a portion of the gate dielectric layer 140 on the mask layer 130 is removed, leaving the gate dielectric layers 142 along the sidewalls of the word lines 152. In this embodiment, the top surfaces of the gate dielectric layers 142 are aligned with the top surfaces of the word lines 152; however, this disclosure is not limited thereto. In other embodiments, the top surfaces of the gate dielectric layers 142 are positioned above the top surfaces of the word lines 152. In other words, the gate dielectric layers 142 extend beyond the top surfaces of the word lines 152.

In this embodiment, each word line 152 includes multiple active portions 152 a in the word line trenches O2a and multiple passing portions 152b in the word line trenches O2b. The active portions 152a and passing portions 152b are connected and arranged alternately (for example, extending in a direction out of the plane of FIG. 1E). The active portions 152a overlap with corresponding active areas AA (not shown in FIG. 1E; refer to FIGS. 2A and 2B), while the passing portions 152b overlap with corresponding shallow trench isolation structures ST. In this embodiment, the depth of the passing portions 152b extending into the substrate 100 is greater than the depth of the active portions 152a extending into the substrate 100.

In some embodiments, after forming the word lines 152, a cleaning process is performed to remove residues generated during etching.

Referring to FIG. 1F, a first barrier material layer 160 is formed over top surfaces of the word lines 152 and sidewalls of the word line trenches O2a and O2b. Specifically, the first barrier material layer 160 extends from the top surface of the mask layer 130 into the word line trenches O2a and O2b, covering the recessed areas on the tops of the active portions 152a and passing portions 152b. In some embodiments, the first barrier material layer 160 comprises an oxide, such as silicon oxide or other suitable materials. In some embodiments, the first barrier material layer 160 may be formed using in situ steam generation (ISSG) process, atomic layer deposition (ALD) process, chemical vapor deposition (CVD) process, thermal oxidation process, or other suitable techniques. In some embodiments, the first barrier material layer 160 may be a High-Quality oxide (HQ oxide). In some embodiments, the first barrier material layer 160 may be composed of a high-k dielectric material (e.g., silicon nitride); however, this is not intended to limit the scope of the present disclosure. The term “high dielectric constant” here is relative to that of silicon dioxide (κ=3.9), with silicon nitride exhibiting a κ value of 7 to 8. Employing a high-k dielectric material for the first barrier material layer 160 can help prevent excessive reductions in saturation current. In some embodiments, the first barrier material layer 160 is formed through atomic layer deposition (ALD) or other suitable methods.

Referring to FIG. 1G, a first semiconductor material layer 170 is formed on the first barrier material layer 160 and in the word line trenches O2a and O2b. The first semiconductor material layer 170 is separated from the mask layer 130 by the first barrier material layer 160. In some embodiments, the first barrier material layer 160 optionally has openings (not shown in the figures), through which the work function control material layer 170 contacts the word lines 152 beneath the first barrier material layer 160.

In this embodiment, the work function of the first semiconductor material layer 170 is lower than that of the word lines 152. For example, the first semiconductor material layer 170 may include a semiconductor material such as polysilicon. The first semiconductor material layer 170 is a doped semiconductor material, with dopant species such as phosphorus, arsenic, or the like.

Referring to FIG. 1H, an etching process (e.g. etching back process) is performed the first semiconductor material layer 170 to release top spaces of the word line trenches O2a and O2b and to form the first doped regions 172.

In some embodiments, the first barrier material layer 160 is also etched during the etching process to form the first barrier layer 162. In certain embodiments, a portion of the first barrier material layer 160 on the mask layer 130 is removed, and the mask layer 130 is exposed after the etching process. Additionally, in some embodiments, portions of the first barrier material layer 160 along the sidewalls of the word line trenches O2a and O2b are retained after etching, and the first barrier layer 162 extends beyond the top surfaces of the first doped regions 172.

In this embodiment, the top surface of the first barrier layer 162 is aligned with the top surface of the substrate 100; however, this disclosure is not limited thereto. In other embodiments, the top surface of the first barrier layer 162 may be positioned higher than the top surface of the substrate 100.

Referring to FIG. 1I, a second semiconductor material layer 180 is formed on the first doped regions 172 in the word line trenches O2a and O2b. The first barrier layer 162 is laterally located between the second semiconductor material layer 180 and the sidewalls of the word line trenches O2a and O2b. In some embodiments, the second semiconductor material layer 180 is formed on the mask layer 130 and is in direct contact with it.

In this embodiment, the work function of the second semiconductor material layer 180 is lower than that of the word lines 152. For example, the second semiconductor material layer 180 may include a semiconductor material such as polysilicon. The second semiconductor material layer 180 is a doped semiconductor material, with dopant species such as phosphorus, arsenic, or the like. The first doped region 172 has a higher dopant concentration than the second semiconductor material layer 180.

FIG. 2B shows a cross-sectional schematic corresponding to the position along line b-b in FIG. 1J, illustrating the second doped regions 182 and the active areas AA of the substrate 100. Referring to FIG. 1J and FIG. 2B, an etching process (e.g. etching back process) is performed on the second semiconductor material layer 180 to form the second doped regions 182. The first doped region 172 and second doped region 182 are physically connected. A portion of the top spaces of the word line trenches O2a and O2b is released by the etching process. In some embodiments, portions of the first barrier layer 162 may be removed during the etching process used to form the second doped region 182; however, this disclosure is not limited thereto. The top surface of the first barrier layer 162 may be aligned with, above, or below the top surface of the second doped region 182.

In this embodiment, work function control structures WF are disposed over the word lines 152. Each work function control structures WF includes a first doped region 172 and a second doped region 182, with the first doped region 172 positioned closer to the word lines 152 than the second doped region 182. The first doped region 172 and the second doped region 182 are composed of the semiconductor material and contain a same dopant species, and the first doped region 172 has a higher dopant concentration than the second doped region 182.

In this embodiment, the first doped region 172, with relatively high conductivity (due to a high doping concentration), enhances current flow. In addition, Short Write Back (SWB) testing is primarily used to detect slowed data transmission caused by abnormal resistance between the cell capacitor and the bitline. Under a limited data write time, this abnormal resistance may lead to data read errors, as it directly impacts the operation of DRAM write data. The device proposed in this disclosure effectively improves the results obtained from the SWB test. At the same time, the second doped region 182, with relatively low conductivity (due to a low doping concentration), helps to mitigate GIDL issues, thereby improving device performance.

Referring to FIG. 1K, a second barrier layer 190 is formed on the top surfaces o work function control structures WF and the first barrier layer 162. In some embodiments, the second barrier layer 190 includes an oxide, such as silicon oxide or other suitable materials. In some embodiments, the second barrier layer 190 may be formed using ISSG process, ALD process, CVD process, a thermal oxidation process, or other suitable techniques. In some embodiments, the second barrier layer 190 may be a High-Quality oxide (HQ oxide). In some embodiments, the second barrier layer 190 may be composed of a high-k dielectric material (e.g., silicon nitride); however, this is not intended to limit the scope of the present disclosure. In some embodiments, the second barrier layer 190 is formed through atomic layer deposition (ALD) or other suitable methods.

Referring to FIG. 1L, a cap layer 200 is formed above both the active portions 152a and the passing portions 152b, and the cap layer 200 is embedded in the substrate 100. In some embodiments, before forming the cap layer 200, the second barrier layer 190 is etched (e.g., through dry etching or another suitable method) to expose the top surface of the mask layer 130, allowing the subsequently formed cap layer 200 to make contact with the mask layer 130. In certain embodiments, the mask layer 130 may be etched during any of the aforementioned etching processes, which could result in the top structure of the mask layer 130 not being flat as shown in the figures. For example, in some embodiments, the mask layer 130 may have a curved top surface.

In some embodiments, the cap layer 200 includes nitrides such as silicon nitride, but the disclosure is not limited thereto. In other embodiments, the cap layer 120 may include oxides such as silicon oxide or other insulating materials. In this embodiment, the cap layer 200 is separated from the work function control structures WF by the second barrier layer 190, but the disclosure is not limited thereto. In other embodiments, the second barrier layer 190 may be omitted, and the cap layer 200 may directly contact the work function control structures WF.

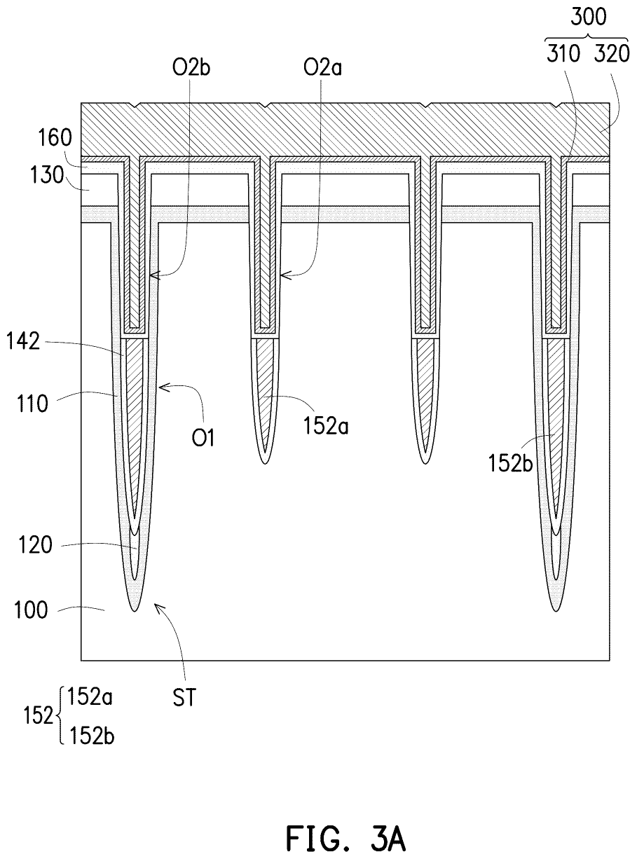

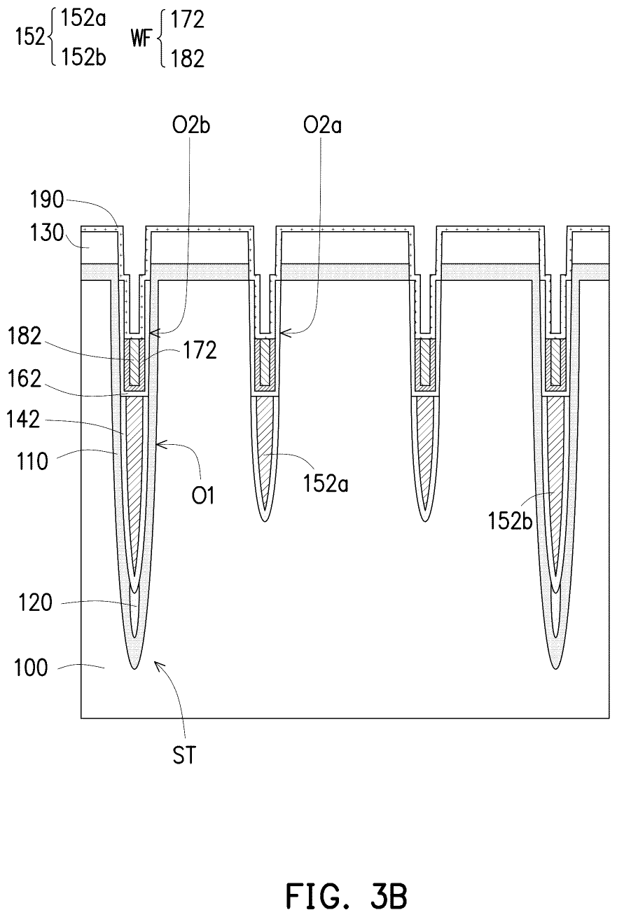

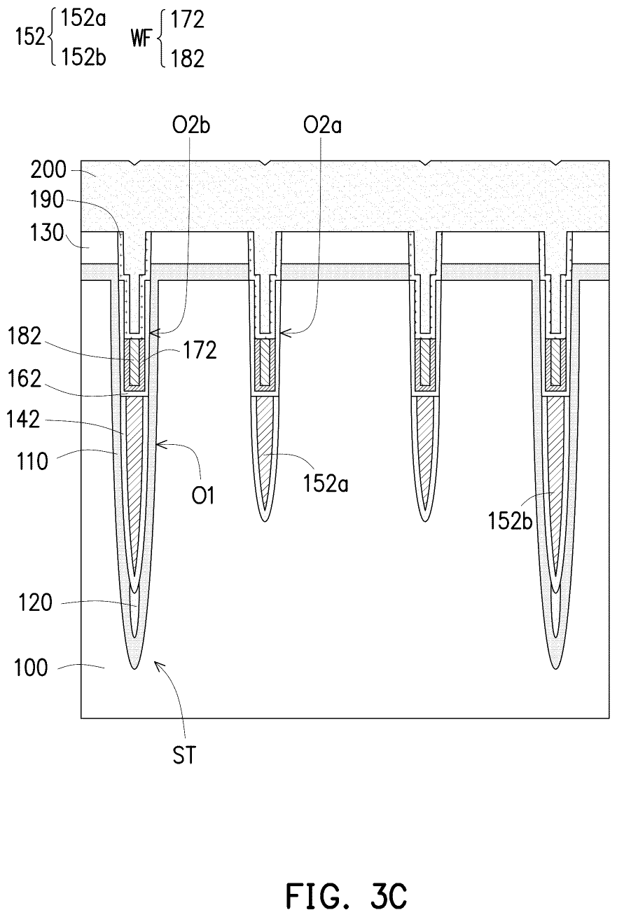

FIGS. 3A to 3C are schematic cross-sectional views of the manufacturing method of a semiconductor structure of the embodiment of the present invention. It should be noted herein that, in embodiments provided in FIG. 3A to FIG. 3C, element numerals and partial content of the embodiments provided in FIG. 1A to FIG. 1L are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 3A, continuing from the step in FIG. 1F, a semiconductor material layer 300 is formed on the first barrier material layer 160. In some embodiments, the method for forming the semiconductor material layer 300 includes CVD process, furnace process, ALD process or other suitable methods. By adjusting process parameters during the formation of the semiconductor material layer 300, regions with different properties are created within the layer. For example, the semiconductor material layer 300 includes a first region 310 at the bottom and a second region 320 at the top, with the first region 310 in contact with the first barrier material layer 160. In some embodiments, the semiconductor material layer 300 is made of doped polysilicon, and the process gases used in forming the semiconductor material layer 300 include amorphous Si, Poly Si, crystal Si or low work function semiconductor material. In some embodiments, the first region 310 and the second region 320 are formed by adjusting the process pressure, process temperature, or other process parameters.

The first region 310 and the second region 320 include the same semiconductor material and contain the same dopant species. However, the first region 310 has a higher dopant concentration than the second region 320.

Referring to FIG. 3B, an etching process (e.g. an etching back process) is performed on the semiconductor material layer 300 to form the first doped region 172 and the second doped region 182. The etched first region 310 forms the first doped region 172, and the etched second region 320 forms the second doped region 182. In this embodiment, the first doped region 172 and the second doped region 182 are defined using a single etching process, thereby reducing process costs. In some embodiments, the first barrier material layer 160 is also etched during the etching process to form the first barrier layer 162.

In this embodiment, the first doped regions 172 of the work function control structures WF are laterally located between the second doped regions 182 of the work function control structures WF and sidewalls of the word line trenches O2a and O2b. In some embodiments, the first doped regions 172 have a cross-sectional shape that is close to a U-shape.

In some embodiments, the dopant concentration in the work function control structures WF is graded, with the dopant concentration increasing closer to the first barrier layer 162.

A second barrier layer 190 is formed over the top surfaces of work function control structures WF and the first barrier layer 162.

Referring to FIG. 3C, a cap layer 200 is formed over the second barrier layer 190. In some embodiments, before forming the cap layer 200, the second barrier layer 190 is etched (e.g., through dry etching or another suitable method) to expose the top surface of the mask layer 130, allowing the subsequently formed cap layer 200 to make contact with the mask layer 130. In certain embodiments, the mask layer 130 may be etched during any of the aforementioned etching processes, which could result in the top structure of the mask layer 130 not being flat as shown in the figures. For example, in some embodiments, the mask layer 130 may have a curved top surface.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate;
a plurality of word lines, located in a plurality of word line trenches of the substrate;
a first barrier layer, disposed on top surfaces of the plurality of word lines;
a plurality of work function control structures, disposed over the plurality of word lines, wherein each of the plurality of work function control structures comprises a first doped region and a second doped region, with the first doped region positioned closer to the plurality of word lines than the second doped region, wherein the first doped region and the second doped region are composed of a semiconductor material and contain a same dopant species, and the first doped region has a higher dopant concentration than the second doped region.

2. The semiconductor structure of claim 1, wherein the first doped region and second doped region are physically connected.

3. The semiconductor structure of claim 1, further comprising:
a second barrier layer, disposed over the plurality of work function control structures; and
a cap layer, disposed over the second barrier layer and embedded in the substrate.

4. The semiconductor structure of claim 1, wherein the first doped regions of the plurality of work function control structures are laterally located between the second doped regions of the plurality of work function control structures and sidewalls of the plurality of word line trenches.

5. The semiconductor structure of claim 1, wherein the semiconductor material is polysilicon, and the same dopant species is phosphorus or arsenic, and wherein the plurality of word lines are titanium nitride.

6. A fabrication method of a semiconductor structure, comprising:
forming a plurality of word line trenches in a substrate;
forming a plurality of word lines in the plurality of word line trenches;
forming a first barrier layer on top surfaces of the plurality of word lines; and
forming a plurality of work function control structures over the plurality of word lines, wherein each of the plurality of work function control structures comprises a first doped region and a second doped region, with the first doped region positioned closer to the plurality of word lines than the second doped region, wherein the first doped region and the second doped region are composed of a semiconductor material and contain a same dopant species, and the first doped region has a higher dopant concentration than the second doped region.

7. The fabrication method of claim 6, wherein a method for forming the plurality of work function control structures comprises:
forming a first semiconductor material layer in the plurality of word line trenches;
etching the first semiconductor material layer to release top spaces of the plurality of word line trenches and to form the first doped regions of the plurality of work function control structures;
forming a second semiconductor material layer on the first doped regions in the plurality of word line trenches; and
etching the second semiconductor material layer to release a portion of the top spaces of the plurality of word line trenches and to form the second doped regions of the plurality of work function control structures.

8. The fabrication method of claim 7, further comprising:
forming a first barrier material layer over top surfaces of the plurality of word lines and sidewalls of the plurality of word line trenches;
forming the first semiconductor material layer on the first barrier material layer; and
etching the first barrier material layer during etching the first semiconductor material layer, and the first barrier layer is formed after etching the first barrier material layer, wherein the first barrier layer extends beyond top surfaces of the first doped regions, wherein the first barrier layer is laterally located between the second semiconductor material layer and the sidewalls of the plurality of word line trenches.

9. The fabrication method of claim 8, further comprising:
forming a mask layer on the substrate;
performing an etching process on the substrate, during which the mask layer is used to define the plurality of word line trenches;
forming the first barrier material layer on the mask layer and in the plurality of word line trenches;
forming the first semiconductor material layer on the first barrier material layer and in the plurality of word line trenches, wherein the first semiconductor material layer is separated from the mask layer by the first barrier material layer;
etching the first barrier material layer to remove a portion of the first barrier material layer on the mask layer;
forming the second semiconductor material layer on the mask layer and in the plurality of word line trenches, wherein the second semiconductor material layer is in contact with the mask layer.

10. The fabrication method of claim 6, wherein a method for forming the plurality of work function control structures comprises:
forming a first barrier material layer over top surfaces of the plurality of word lines and sidewalls of the plurality of word line trenches;
forming a semiconductor material layer on the first barrier material layer, wherein the semiconductor material layer comprises a first region at bottom and a second region at top, with the first region in contact with the first barrier material layer, wherein the first region and the second region are composed of the semiconductor material and contain the same dopant species, and the first region has a higher dopant concentration than the second region;
etching the semiconductor material layer to form the first doped region and the second doped region; and
etching the first barrier material layer during etching the semiconductor material layer, and the first barrier layer is formed after etching the first barrier material layer.
